(19) United States
(12) Patent Application Publication
(10) Pub. No.: US 2024/0063795 A1
(43) Pub. Date: Feb. 22, 2024

(54) Self-Timed Delayed Keeper for Dynamic Logic

(71) Applicant: APPLE INC., Cupertino, CA (US)

(72) Inventors: Andrew Russell, Austin, TX (US); Michael A. Dreesen, Aistin, TX (US); Adam Johnson, Austin, TX (US); Jacek R. Wiatrowski, Austin, TX (US)

(21) Appl. No.: 18/108,624

(22) Filed: Feb. 12, 2023

Related U.S. Application Data
(60) Provisional application No. 63/398,238, filed on Aug. 16, 2022.

(51) Int. Cl. H03K 19/003; G01R 31/3177

(52) U.S. Cl. CPC H03K 19/00315; G01R 31/3177

(57) ABSTRACT

An electronic circuit for dynamic evaluation of logic functions includes a discharging circuit, a first keeper circuit, a delay circuit and a second keeper circuit. The discharging circuit is configured to discharge an evaluation node. The first keeper circuit is configured to charge the evaluation node and configured to be disabled responsively to a first keeper control indication. The delay circuit is configured to generate a second keeper control indication that is delayed relative to the first keeper control indication. The second keeper circuit is configured to retain a charge on the evaluation node responsively to the second keeper control indication.

### CROSS-REFERENCE TO RELATED APPLICATIONS

This application claims the benefit of U.S. Provisional Patent Application 63/398,238, filed Aug. 16, 2022, whose disclosure is incorporated herein by reference.

### FIELD OF THE DISCLOSURE

The present disclosure relates generally to integrated circuits, and specifically to self-timed keeper circuits in dynamic logic.

### BACKGROUND OF THE DISCLOSURE

In dynamic logic, reliably discharging a pre-charged dynamic node at low voltage and temperature can be challenging, because the increased Vt weakens the NMOS discharging device relative to the dynamic keeper PMOS device.

### SUMMARY OF THE DISCLOSURE

An embodiment described herein provides an electronic circuit for dynamic evaluation of logic functions. The electronic circuit includes a discharging circuit, a first keeper circuit, a delay circuit and a second keeper circuit. The discharging circuit is configured to discharge an evaluation node. The first keeper circuit is configured to charge the evaluation node and configured to be disabled responsively to a first keeper control indication. The delay circuit is configured to generate a second keeper control indication that is delayed relative to the first keeper control indication. The second keeper circuit is configured to retain a charge on the evaluation node responsively to the second keeper control indication.

In some embodiments, the electronic circuit further includes a self-timing circuit, which is configured to generate the first keeper control indication responsively to an activation of a data input of the discharging circuit. In an embodiment, a delay of the delay circuit depends on a duration of a discharge phase of the discharging circuit. In an example embodiment, the first keeper control indication includes an indication that the discharge circuit is not discharging the evaluation node.

In a disclosed embodiment, the electronic circuit further includes a pre-charging circuit configured to charge the evaluation node at a predefined phase of a clock, wherein the pre-charging circuit and the discharging circuit are associated with different voltage domains. In an embodiment, the delay circuit includes a cascade of an odd number of inverting gates.

In some embodiments, the discharging circuit includes a comparator. In an example embodiment, the first keeper control indication includes one or more signals on one or more respective bit-lines of the comparator. In an embodiment, the discharging circuit is a comparison array including at least two one-bit-comparison discharging circuits, and the first keeper control indication is indicative of an input to one or more of the one-bit-comparison discharging circuits.

There is additionally provided, in accordance with an embodiment described herein, a method of operating an electronic circuit. The method includes, responsive to activation of a data input signal of the electronic circuit, decoupling an evaluation node of the electronic circuit from a precharge voltage. During a delay period in which the evaluation node is decoupled from the precharge voltage, the evaluation node is discharged. Responsive to termination of the delay period, the evaluation node is coupled to the precharge voltage. The delay period is shorter than an evaluation phase defined by a clock input to the electronic circuit.

There is also provided, in accordance with an embodiment described herein, a method of operating an electronic circuit. The method includes discharging an evaluation node using a discharging circuit, and charging the evaluation node using a first keeper circuit. Responsively to a first keeper control indication, (i) the first keeper circuit is disabled, and (ii) a second keeper control indication, which is delayed relative to the first keeper control indication, is generated. Using a second keeper circuit, a charge is retained on the evaluation node responsively to the second keeper control indication.

### BRIEF DESCRIPTION OF THE DRAWINGS

FIG. 1 is a block diagram that schematically illustrates a dynamic comparator with a self-timed delayed keeper, in accordance with an embodiment that is described herein;

FIG. 2 is a waveform diagram that schematically illustrates the waveform of a dynamic logic circuit with a self-timed delayed keeper, in accordance with an embodiment that is described herein;

FIG. 3 is a block diagram that schematically illustrates a dual-array dynamic comparator with a self-timed delayed keeper, in accordance with an embodiment that is described herein;

FIG. 4 is a flowchart that schematically illustrated a method for operating an electronic circuit, in accordance with embodiments that are described herein;

FIG. 5 is a diagram that schematically illustrates various types of systems that may include any of the circuits, devices, or system discussed above, in accordance with embodiments that are described herein; and

FIG. 6 is a block diagram illustrating an example non-transitory computer-readable storage medium that stores circuit design information, in accordance with embodiments described herein.

### DETAILED DESCRIPTION OF EMBODIMENTS

### Overview

Dynamic logic circuits include an evaluation node that is precharged at a precharge phase, and then conditionally discharged at a subsequent evaluation phase. Typically, the precharge is done by P-type Metal-Oxide-Silicon (PMOS) transistors, whereas the conditional discharge is done by N-type Metal-Oxide-Silicon (NMOS) transistors. To avoid charge loss (e.g., due to leakage) during the evaluation phase (in case there is no conditional discharge), keeper circuits can be used, wherein a PMOS transistor keeps the evaluation node from discharging.

Due to Process-Voltage-Temperature (PVT) variations, coupled with the use of multiple voltage domains, it is not easy to guarantee that the discharge circuit will always prevail over the keeper circuit if both are active at the same time.

Embodiments that are disclosed herein provide for timed keeper circuits that are disabled during part of the evaluation phase, to avoid contention between the discharge and the keeper transistors. In an embodiment, the keeper circuit includes a keeper-1 circuit, and a keeper-2 circuit; keeper-1 circuit charges the evaluation node starting at the beginning of the evaluation phase and ending at a time that matches the start of the discharge of the evaluation node; in case the evaluation node is not discharged, keeper-2 keeps the evaluation node charged after a time that matches the worst-case discharge time. Thus, in embodiments, both evaluation node float time (and consequent leakage) and the contention between the keeper circuits and discharge circuits are minimized.

In embodiments, the control inputs that start the discharge are used to disable keeper-1 and, hence, keeper-1 is self-timed. In some embodiments, the circuit that drives keeper-2 and the discharge circuits include the same type of transistors, and thus, the delay of keeper-2 can be matched to the delay of the discharge circuit.

### DESCRIPTION OF EMBODIMENTS

Dynamic logic circuitry typically includes evaluation nodes, precharge circuits and discharge circuits. The precharge circuits precharge the evaluation nodes (e.g., to logic-high) at a first phase of a clock, and the discharge circuit may or may not discharge the evaluation node at a second phase of the clock, depending on the logic level of signals, and on the predefined logic functions. We will refer below to the two phases as a precharge phase and an evaluation phase.

As an example, a dynamic circuit that checks whether two binary words are identical may include an evaluation node that is precharged at a precharge phase, and discharge circuits, one for every pair of corresponding bits of the two words, to discharge the evaluation node at the evaluation phase if any pair of corresponding bits of the two binary words are not identical.

If, during the discharge phase, the discharge circuit does not discharge the evaluation node, the evaluation node should remain at the precharge logic level, despite inherent process leakage and at all specified clock frequencies. To meet this requirement, dynamic logic circuits may include one or more keeper circuits that are configured to actively pull the evaluation node to the precharge logic level.

We will refer hereinbelow to the precharge logic level as high; we will assume P-type precharge transistors (PMOS) and N-type transistors (NMOS) in the discharge circuits. Other embodiments, however, may use any logic level for the precharge and the discharge phases, and any suitable transistor (or other device) types.

The discharge of the evaluation node at low voltage and temperature can be challenging, since the increased Vt weakens the NMOS pulldown, which still has to overpower the keeper device.

One technique to ensure that an evaluation node can be discharged at low voltage is to temporarily disable the keeper just before the NMOS discharge circuit discharges the evaluation node, so that the NMOS discharge circuit does not have to “fight” the keeper.

However, when some of the signals associated with the discharge circuits originate in a different voltage domain and/or input from a circuit that is physically remote from the discharge circuit, generating a precisely timed keeper-disable signal may not be easy. Stretching the disable-time more than needed may increase the float time of the evaluation node, resulting in voltage drop due to leakage.

In embodiments, the keeper disable signal uses the same signals that drive the discharge circuit and, hence, the disable signal is self-timed to match the start delay of the discharge circuit.

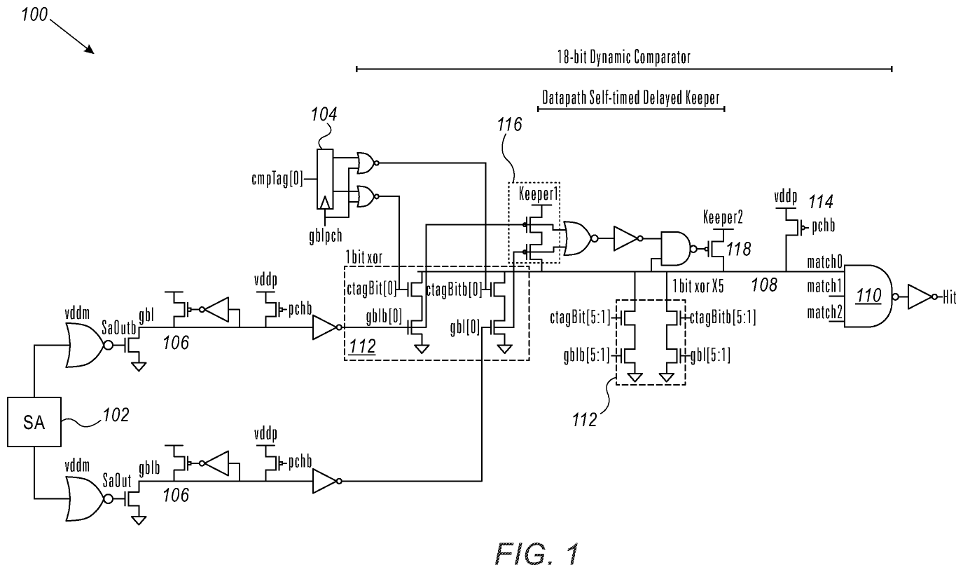

FIG. 1 is a block diagram that schematically illustrates a dynamic comparator 100 with a self-timed delayed keeper, in accordance with an embodiment that is described herein. The comparator is configured to compare 18 bits that are read from sense amplifiers 102 (one sense amplifier is shown) to 18 corresponding tag register bits 104 (one is shown).

As will be described hereinbelow, dynamic comparator 100 includes a first and a second dynamic stages, wherein the first stage drives the second stage. According to the example embodiment illustrated in FIG. 1, only the second stage includes a self-timed delayed keeper; in alternative embodiments, however, either or both dynamic stages may include self-timed delayed keepers.

Each sense amplifier 102 includes two complementary outputs; the sense amplifier drives one output high and the other output low, responsively to the polarity of the sensed bit (in embodiments, SA 102 may include a Random Access Memory (RAM) sense amplifier, coupled to a word line thereof). The two complementary outputs are coupled to a first dynamic stage, including precharged bit-line evaluation nodes 106, each precharged bit-line evaluation node including a precharge device and a keeper. During the precharge phase, the inverted outputs of evaluation nodes 106, designated gbl[0] and gblb[0], are at logic 0. At the evaluation phase, if the bit read by SA 102 is logic high, gbl[0] will assume a logic high level while gblb[0] will remain at logic low, and if the read bit is logic low, gblb[0] will assume a logic high level while gbl[0] will remain at logic low.

Comparator 100 includes three second stage evaluation nodes 108, that are input to a NAND gate 110. The evaluation nodes are designated match0, match1 and match2 (only match0 is shown in FIG. 1). Each evaluation node includes six one-bit XOR circuits 112 that compare gbl[i] to corresponding tag bits cmpTag[i]. (For clarity, only cmpTag[0] is shown in FIG. 1).

Evaluation node 108 further includes a precharge device 114, a Keeper-1 circuit 116, and a Keeper-2 circuit 118. Keeper-1 circuit includes two serially connected PMOS devices; hence, Keeper-1 will pull the evaluation node high only when both gbl[0] and gblb[0] are at logic low; when either gbl[0] or gblb[0] turns high, Keeper-1 will turn-off, allowing the one-bit XOR circuits to discharge the evaluation node.

Since SA 102 operation is delayed relative to the start of the evaluation phase, the disabling of Keeper-1 is self-timed to when the sense amplifier has fired and the discharge XOR circuits may start discharging the evaluation node; thus, the floating time of the evaluation node is reduced. (We assume that the timing of all sense amplifiers that are coupled to the same evaluation node is similar.)

At a given delay time after one of gbl[0] or gblb[0] turns on, if the evaluation node has not been discharged, the gate of Keeper-2 turns on (logic-low), and Keeper 2 will keep the evaluation node high (if the evaluation node is low, the NAND gate will keep Keeper-2 off). In embodiments, the delay from gbl[0] or gblb[0] rising edge to the enabling of Keeper-2 is timing-matched to the discharge time of the evaluation node when discharged by a single XOR circuit and, thus, Keeper-2 does not collide with the discharging circuits.

The configuration of dynamic comparator 100 illustrated in FIG. 1 and described hereinabove is cited by way of example; other configurations may be used in alternative embodiments. For example, the illustrated keeper-2 driving stages, including a NOR gate, an Inverter and a NAND gate may be different, as long as the delay through the driving stages matches the discharge time of a single XOR circuit (and as long as an odd number of inversions is implemented). In some embodiments, circuit 100 is a dynamic circuit other than a comparator with the discharging and keeper circuits accordingly modified. In embodiments, different number of evaluation lines may be used (and, accordingly, the number of NAND gate 110 inputs will change). In various embodiments, a different number of one-bit XOR discharge circuits may be coupled to each evaluation node.

In some embodiments, comparator 100 is ternary, and tag bits may assume a don't care value, in which both ctag-Bit and ctag-Bitb are at logic low.

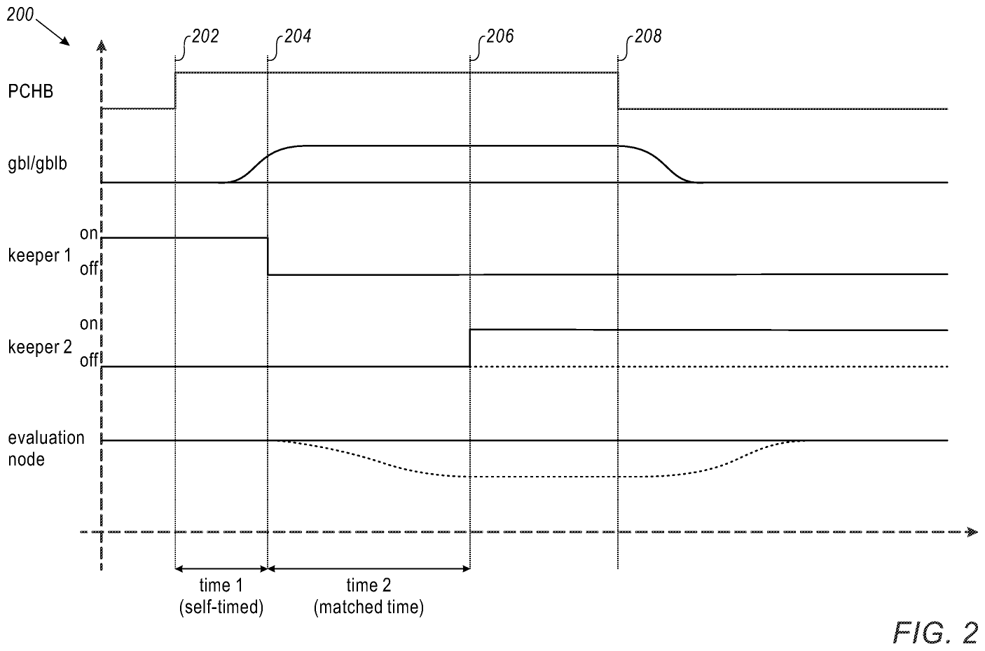

FIG. 2 is a waveform diagram 200 that schematically illustrates the waveforms of a dynamic logic circuit with a self-timed delayed keeper, in accordance with an embodiment that is described herein. The waveform diagram illustrates the voltage levels on PCHB (precharge-bar) clock, applied to the gate of a precharge transistor coupled to an evaluation node, gbl/gblb bit-lines, Keeper-1, Keeper-2 and evaluation node 108 (all signals referring to FIG. 1).

The timing waveforms starts at the precharge phase, with PCHB at logic low, and the evaluation node at high voltage. The Evaluation phase starts at a timepoint 202; PCHB turns off; at the same time, (not shown in FIG. 2), sense amplifiers 102 (FIG. 1) detects stored bits on the bit lines, and one of the pair of stage-1 evaluation nodes start discharging, according to the stored bits. Then, at a time point 204, the voltage on one of gbl[0], gblb[0] starts rising, and, responsively, one or more of XOR circuits 112 may start discharging the evaluation node (the XOR circuits for which gbl is not equal to the corresponding cmpTag bit).

When the rising gbl or gblb wire reaches the corresponding threshold of Keeper-1 PMOS device, Keeper-1 turns off allowing any discharging XOR circuits to discharge the evaluation node (the evaluation node will not be discharged if all gbl values match the corresponding cmpTag bit values).

After another delay (set by the inverting logic stages of Keeper 2), if the evaluation node has not been discharged, Keeper-2 will turn on, and keep the voltage of the evaluation node high.

The time period from time point 202 to time point 204 is designated self-time 1; in embodiments, self-time 1 is configured to match the delay from the start of the evaluation phase to the beginning of the discharge by XOR circuits 112. The time period from time point 204 and time point 206 is designated matched-time 2. In embodiments, matched-time 2 is configured to match the slowest discharge time of the evaluation node.

At a time point 208, PCHB turns low and the next precharge phase starts.

In some embodiments, the dynamic comparator may include a plurality of arrays, e.g., a left array and a right array, that share a common evaluation node; at any given time, one of the arrays may be selected to be compared to the set of cmpTag bits.

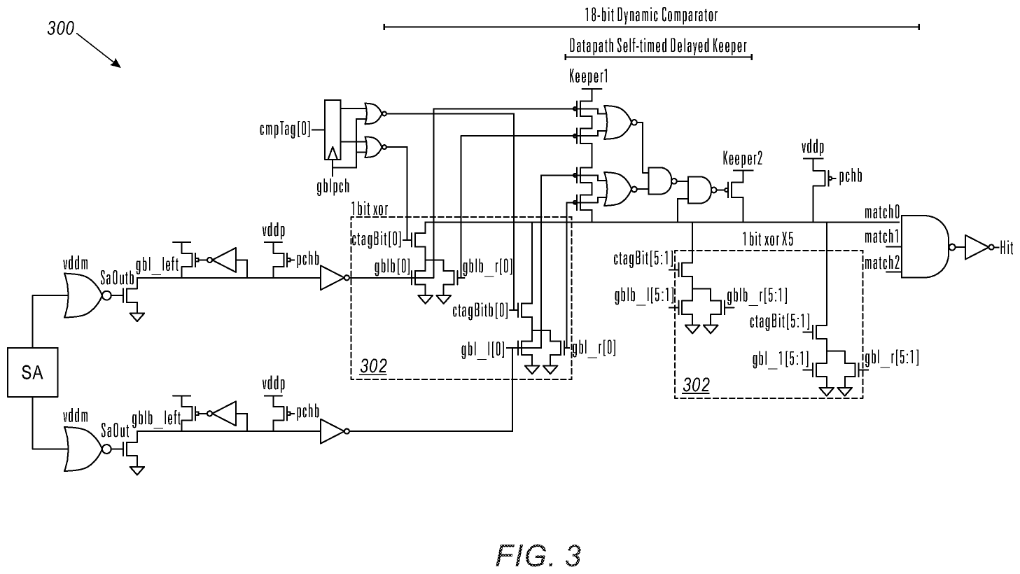

FIG. 3 is a block diagram that schematically illustrates a dual-array dynamic comparator 300 with a self-timed delayed keeper, in accordance with an embodiment that is described herein.

Dynamic logic circuit 300 is similar to dynamic logic circuit 100 (FIG. 1), except that the one-bit XOR circuits and the keeper circuits of circuit 300 are configured to handle pairs of bits, from the two arrays.

A XOR 302 circuit receives gbl-l/gblb-l wires from the left array, and gbl-r/gblb-r from the right array. As only one of the arrays may be selected at a time, either the pair gbl-r/gblb-r or the pair gbl-l/gblb-l will be at logic low (the other pair will have one line at low and the other at high). Thus, XOR circuit 302 compares the bit from the selected array to the common cmpTag bit.

Keeper-1 circuit of comparator 300 has four serially connected PMOS devices, so that, if any of gbl-r, gblb-r, gbl-l, gblb-l wires is high, keeper 1 will be disabled. Similarly, Keeper-2 circuit of comparator 300 includes four inputs and turns on (after a delay) if one of gbl-r, gblb-r, gbl-l or gblb-l is at logic high and if the evaluation node is not discharged.

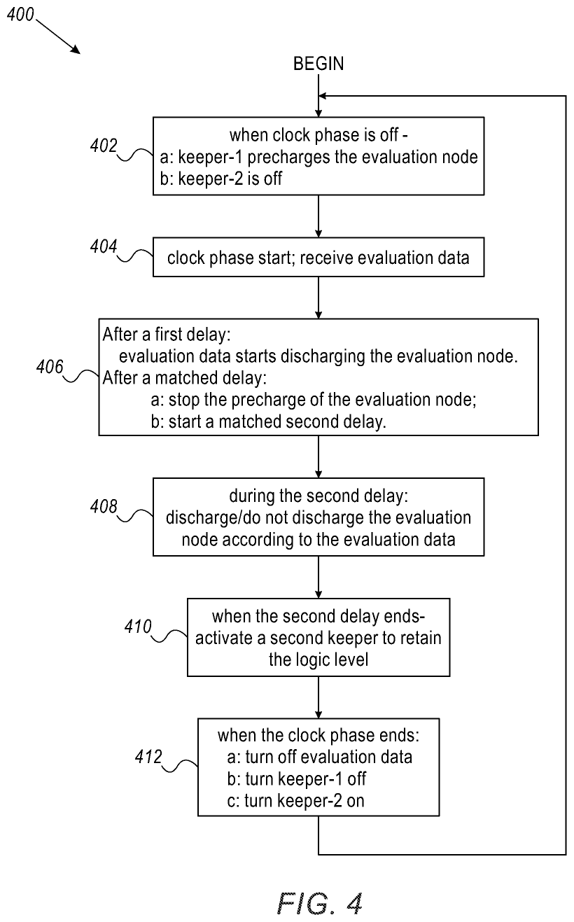

FIG. 4 is a flowchart 400 that schematically illustrates a method for operating an electronic circuit, in accordance with embodiments that are described herein. The flowchart is executed by various elements of the electronic circuit that are shown in FIG. 1, as described below.

The flowchart starts at a Clock-Phase-Off operation 402, wherein the clock input is off (e.g., low) and the electronic circuit activates keeper-1 116 to precharge the evaluation node and deactivates keeper-2 118.

Then, at a Start-Clock-Phase operation 404, when the clock input turns high, and the clock phase starts, the circuit receives the data to be evaluated, typically from a previous computation stage.

At an After-First-Delay operation 406, the evaluation data starts discharging the evaluation node (e.g., reaches XOR circuit 112). After a self-timed delay (which is adjusted to match the first delay) from the start of the clock phase, the circuit turns keeper-1 off, whereby stopping the precharge operation (so that the evaluation node could be discharged) and starts a second delay period.

Next, at a Second-Delay operation 408, the electronic circuit (e.g., XOR circuit 112), during the second delay period, discharges the evaluation node or keeps the evaluation node high, according to the evaluation data.

Then, when the second delay ends, the electronic circuit, at an Activate-Second-Keeper operation 410, activates keeper-2, to retain the logic state of the evaluation node.

Lastly, at an End-of-Clock-Phase operation 412, the electronic circuit turns off the evaluation data (e.g., sets the data low), turns keeper-1 off and turns keeper-2 on. The flowchart then returns to operation 402.

The configuration of dynamic comparator 300 illustrated in FIG. 3 and described herein is cited by way of example. Other configurations may be used in alternative embodiments. For example, in some embodiments, keeper-1 and/or keeper-2 may be replicated (e.g., at both sides of the evaluation node.

The configuration of dynamic comparators 100 and 300, including XOR circuits 112, 302, keeper-1 circuits and keeper-2 circuits; and waveform 200, including all subunits thereof, as well as flowchart 400, are example configurations waveforms and flowcharts that are shown purely for the sake of conceptual clarity. Any other suitable configurations and waveforms can be used in alternative embodiments, including, for example, self-timed keepers of dynamic logic circuits other than comparators. In particular, it is noted that circuits 112 and/or 302 may be reconfigured to implement any suitable Boolean logic function, and may thus be deployed in any circuit involving digital computation. For example, while the comparator embodiments discussed above may be used within cache circuits to perform tag comparisons to determine cache hit/miss status, other configurations may be employed as part of other storage circuits (e.g., content addressable memories (CAMs)), datapath circuits (e.g., arithmetic-logic units (ALUs)), control circuits (e.g., state machines), or other digital logic applications.

In various embodiments, dynamic comparator 100 and 300 or subunits thereof may be implemented using suitable hardware, such as one or more Application-Specific Integrated Circuits (ASIC) or Field-Programmable Gate Arrays (FPGA), or a combination of ASIC and FPGA.

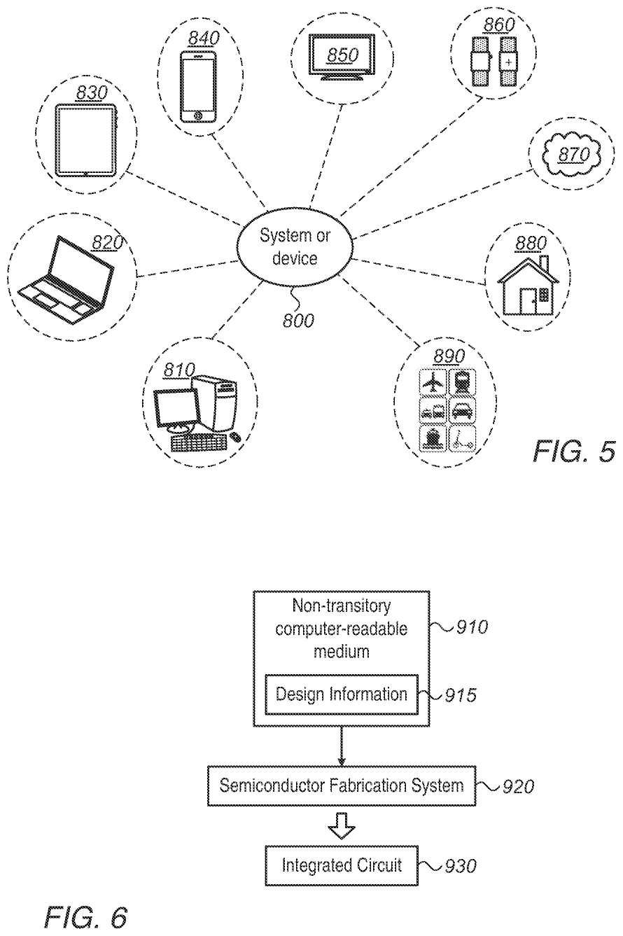

FIG. 5 is a diagram 800 that schematically illustrates various types of systems that may include any of the circuits, devices, or system discussed above, in accordance with embodiments that are described herein. System or device 800, which may incorporate or otherwise utilize one or more of the techniques described herein, may be utilized in a wide range of areas. For example, system or device 800 may be utilized as part of the hardware of systems such as a desktop computer 810, laptop computer 820, tablet computer 830, cellular or mobile phone 840, or television 850 (or set-top box coupled to a television).

Similarly, disclosed elements may be utilized in a wearable device 860, such as a smartwatch or a health-monitoring device. Smartwatches, in many embodiments, may implement a variety of different functions, for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 800 may also be used in various other contexts. For example, system or device 800 may be utilized in the context of a server computer system, such as a dedicated server or on shared hardware that implements a cloud-based service 870. Still further, system or device 800 may be implemented in a wide range of specialized everyday devices, including devices 880 commonly found in the home such as refrigerators, thermostats, security cameras, etc. The interconnection of such devices is often referred to as the “Internet of Things” (IoT). Elements may also be implemented in various modes of transportation. For example, system or device 800 could be employed in the control systems, guidance systems, entertainment systems, etc. of various types of vehicles 890.

The applications illustrated in FIG. 5 are merely exemplary and are not intended to limit the potential future applications of disclosed systems or devices. Other example applications include, without limitation: portable gaming devices, music players, data storage devices, unmanned aerial vehicles, etc.

The present disclosure has described various example circuits in detail above. It is intended that the present disclosure cover not only embodiments that include such circuitry, but also a computer-readable storage medium that includes design information that specifies such circuitry. Accordingly, the present disclosure is intended to support claims that cover not only an apparatus that includes the disclosed circuitry, but also a storage medium that specifies the circuitry in a format that is recognized by a fabrication system configured to produce hardware (e.g., an integrated circuit) that includes the disclosed circuitry. Claims to such a storage medium are intended to cover, for example, an entity that produces a circuit design, but does not itself fabricate the design.

FIG. 6 is a block diagram illustrating an example non-transitory computer-readable storage medium that stores circuit design information, according to some embodiments. In the illustrated embodiment semiconductor fabrication system 920 is configured to process the design information 915 stored on non-transitory computer-readable medium 910 and fabricate integrated circuit 930 based on the design information 915.

Non-transitory computer-readable storage medium 910, may include any of various appropriate types of memory devices or storage devices. Non-transitory computer-readable storage medium 910 may be an installation medium, e.g., a CD-ROM, floppy disks, or tape device; a computer system memory or random-access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. Non-transitory computer-readable storage medium 910 may include other types of non-transitory memory as well or combinations thereof. Non-transitory computer-readable storage medium 910 may include two or more memory mediums which may reside in different locations, e.g., in different computer systems that are connected over a network.

Design information 915 may be specified using any of various appropriate computer languages, including hardware description languages such as, without limitation: VHDL, Verilog, SystemC, SystemVerilog, RHDL, M, MyHDL, etc. Design information 915 may be usable by semiconductor fabrication system 920 to fabricate at least a portion of integrated circuit 930. The format of design information 915 may be recognized by at least one semiconductor fabrication system 920. In some embodiments, design information 915 may also include one or more cell libraries which specify the synthesis, layout, or both of integrated circuit 930. In some embodiments, the design information is specified in whole or in part in the form of a netlist that specifies cell library elements and their connectivity. Design information 915, taken alone, may or may not include sufficient information for fabrication of a corresponding integrated circuit. For example, design information 915 may specify the circuit elements to be fabricated but not their physical layout. In this case, design information 915 may need to be combined with layout information to actually fabricate the specified circuitry.

Integrated circuit 930 may, in various embodiments, include one or more custom macrocells, such as memories, analog or mixed-signal circuits, and the like. In such cases, design information 915 may include information related to included macrocells. Such information may include, without limitation, schematics capture database, mask design data, behavioral models, and device or transistor level netlists. As used herein, mask design data may be formatted according to graphic data system (GDSII), or any other suitable format.

Semiconductor fabrication system 920 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 920 may also be configured to perform various testing of fabricated circuits for correct operation.

In various embodiments, integrated circuit 930 is configured to operate according to a circuit design specified by design information 915, which may include performing any of the functionality described herein. For example, integrated circuit 930 may include any of various elements shown in FIGS. 1, 2 and 3. Further, integrated circuit 930 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” or is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement. The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

1. An electronic circuit for dynamic evaluation of logic functions, the electronic circuit comprising:
a discharging circuit configured to discharge an evaluation node;
a first keeper circuit, configured to charge the evaluation node and configured to be disabled responsively to a first keeper control indication;
a delay circuit, configured to generate a second keeper control indication that is delayed relative to the first keeper control indication; and
a second keeper circuit, configured to retain a charge on the evaluation node responsively to the second keeper control indication.

2. The electronic circuit according to claim 1, further comprising a self-timing circuit, which is configured to generate the first keeper control indication responsively to an activation of a data input of the discharging circuit.

3. The electronic circuit according to claim 1, wherein a delay of the delay circuit depends on a duration of a discharge phase of the discharging circuit.

4. The electronic circuit according to claim 1, wherein the first keeper control indication comprises an indication that the discharge circuit is not discharging the evaluation node.

5. The electronic circuit according to claim 1, further comprising a pre-charging circuit configured to charge the evaluation node at a predefined phase of a clock, wherein the pre-charging circuit and the discharging circuit are associated with different voltage domains.

6. The electronic circuit according to claim 1, wherein the delay circuit comprises a cascade of an odd number of inverting gates.

7. The electronic circuit according to claim 1, wherein the discharging circuit comprises a comparator.

8. The electronic circuit according to claim 7, wherein the first keeper control indication comprises one or more signals on one or more respective bit-lines of the comparator.

9. The electronic circuit according to claim 1, wherein the discharging circuit is a comparison array comprising at least two one-bit-comparison discharging circuits, and wherein the first keeper control indication is indicative of an input to one or more of the one-bit-comparison discharging circuits.

10. A method of operating an electronic circuit, the method comprising:
responsive to activation of a data input signal of the electronic circuit, decoupling an evaluation node of the electronic circuit from a precharge voltage;
during a delay period in which the evaluation node is decoupled from the precharge voltage, discharging the evaluation node; and
responsive to termination of the delay period, coupling the evaluation node to the precharge voltage, wherein the delay period is shorter than an evaluation phase defined by a clock input to the electronic circuit.

11. A method of operating an electronic circuit, the method comprising:
discharging an evaluation node using a discharging circuit, and charging the evaluation node using a first keeper circuit;
responsively to a first keeper control indication, (i) disabling the first keeper circuit, and (ii) generating a second keeper control indication that is delayed relative to the first keeper control indication; and
using a second keeper circuit, retaining a charge on the evaluation node responsively to the second keeper control indication.

12. The method according to claim 11, further comprising generating the first keeper control indication responsively to an activation of a data input of the discharging circuit.

13. The method according to claim 11, wherein the second keeper control indication is delayed relative to the first keeper control indication by a delay that depends on a duration of a discharge phase of the discharging circuit.

14. The method according to claim 11, wherein the first keeper control indication comprises an indication that the discharge circuit is not discharging the evaluation node.

15. The method according to claim 11, further comprising charging the evaluation node at a predefined phase of a clock using a pre-charging circuit, wherein the pre-charging circuit and the discharging circuit are associated with different voltage domains.

16. The method according to claim 11, wherein generating the second keeper control indication comprises delaying the first keeper control indication using a cascade of an odd number of inverting gates.

17. The method according to claim 11, wherein the discharging circuit comprises a comparator.

18. The method according to claim 17, wherein the first keeper control indication comprises one or more signals on one or more respective bit-lines of the comparator.

19. The method according to claim 11, wherein the discharging circuit is a comparison array comprising at least two one-bit-comparison discharging circuits, and wherein the first keeper control indication is indicative of an input to one or more of the one-bit-comparison discharging circuits.
